(19) United States
(12) Patent Application Publication
(10) Pub. No.: US 2013/0068723 A1
(43) Pub. Date: Mar. 21, 2013

(54) Method of Using a Mask to Provide a Patterned Substrate

(71) Applicants: Matthew S. Stay, St. Paul, MN (US); Mikhail L. Pekurovsky, Bloomington, MN (US)

(72) Inventors: Matthew S. Stay, St. Paul, MN (US); Mikhail L. Pekurovsky, Bloomington, MN (US)

(21) Appl. No.: 13/518,915

(22) PCT Filed: Dec. 20, 2010
(86) PCT No.: PCT/US10/61195

§ 371 Date: Jun. 25, 2012

Related U.S. Application Data
(60) Provisional application No. 61/291,053, filed on Dec. 30, 2009.

(51) Int. Cl. H05K 3/10

(52) U.S. Cl. CPC H05K 3/10
USPC 216/41; 427/98.5

(57) ABSTRACT

A method of producing substrates having a patterned mask layer with fine features such as repeating stripes. The method including the steps of forming a substrate having a transfer layer with a predetermined pattern on a first major surface of the substrate; providing the substrate having the transfer layer on the first major surface; providing a structured tool having a body and a plurality of contact portions, the contact portions having a Young's Modulus between about 0.5 Gpa to about 30 Gpa; heating either the structured tool or the substrate; contacting the transfer layer with the structured tool; cooling the transfer layer; and withdrawing the structured tool from the transfer layer such that portions of the transfer layer separate with the structured tool leaving openings in the transfer layer that extend all the way through the transfer layer to the substrate forming the transfer layer with the predetermined pattern.

### TECHNICAL FIELD

The present invention concerns the manufacture of substrates having patterned features on their surface, and more particularly to the use of masks that allow patterns with very small features to be formed on a substrate.

### BACKGROUND

Modern manufacturing finds numerous uses for substrates having a second substance layered on the surface in a predetermined pattern. As one well known example, printed circuit boards have a patterned layer of copper on one or both surfaces to provide conductive traces. More recently, industry has found uses for patterns formed of more exotic materials with ever finer dimensions. For example, transparent touch-screen sensors have a substrate, such as glass, with patterned traces made from indium-tin-oxide. The patterned traces can be formed with a screen-printed mask. Screen printing technology, in a manufacturing environment, has a minimum feature resolution of approximately 50 microns or greater. Alternatively, step and repeat photolithography can achieve finer feature resolutions approaching 25 microns, but such a process is not well adapted for producing such fine patterns over the entire surface of larger sized substrates.

Sophisticated new products could be made in the fields of touch sensors, optical displays, EMI shielding, flexible circuits, and active signage display units, if an efficient manufacturing technology existed that allowed for finer patterns or for larger sized patterned substrates to be manufactured efficiently.

### SUMMARY

The present invention provides a way to produce substrates having a patterned layer with either much finer features than has previously been possible using screen printing technology, or to be made more efficiently by an apparatus that can form patterned masks on indefinite length webs in a roll to roll process.

A method for patterning polymer films using an elastomeric stamp is disclosed in U.S. Pat. No. 6,966,997. However, for certain patterns such as a repeating hexagonal pattern (honeycomb pattern) where the individual traces are more widely separated, an elastomeric stamp does not work. It has been found that the contact portions of the elastomeric stamp, forming the hexagonal pattern which extends from the stamp's body, compress too much allowing the stamp's body portion to contact the substrate ruining the fine pattern of printed hexagonal traces. Additionally, the process used to make the elastomeric stamp (photolithography) results in a stamp having square or rectangular features extending from the stamp body with a flat, horizontal surface that contacts the substrate in use. Such a configuration for the contact portions of the stamp's features can limit the minimum width for electrical traces produced by the stamp process.

The inventors have determined that a structured tool, having more rigidity than an elastomeric stamp, solves the problem of too much compliance when using an elastomeric stamp. Desirably, the structured tool is semi-rigid such that it can conform slightly to the substrate, but much less rigid than an embossing roll or tool made from metal. The desired compliance assures that the contact potions of the structured tool can all touch the substrate's surface (even when there are subtle height variations of the contact portions) without unduly deforming or embossing the substrate's surface during use. The desired rigidity also allows for more widely separated patterns or features to be placed onto the substrate without ruining those features by inadvertently contacting the substrate with the structured tool in areas that are intended to be free of the desired pattern.

At least the contact portions of the structured tool should be semi-rigid. The body portion of the structured tool could be made of another material having much higher rigidity, but in many instances it will also be made out of the same material as the contact portions. Young's Modulus (Modulus of Elasticity) for typical elastomeric stamps is commonly between about 0.5 to about 3 Mpa. Often these stamps are made from polydimethylsiloxane materials (PDMS). On the other hand, rigid materials such as aluminum, brass, steel, and tungsten have a Young's modulus between 69 to 410 GPa. The inventors have determined that an elastic modulus greater than that of elastomeric materials is desired, but also one less than that of rigid materials should be employed to allow for more compliance during the printing operation. In various embodiments of the invention, Young's Modulus for the material forming the contact portions should be between about 0.5 to about 30 Gpa, or between about 1 to about 10 GPa, or between about 2 to about 8 Gpa, or between about 3 to about 7 Gpa. In a preferred embodiment, the entire structured tool including the contact portions is made from acrylate resins having a Young's Modulus between about 4 to about 6 Gpa.

It is often convenient for the structured tool to comprise a body portion having the plurality of contact portions thereon. These contact portions will often have a characteristic height by which they tend to extend from the body. In many convenient embodiments this characteristic height will be greater than the thickness of a transfer layer removed from the substrate when contacting the substrate with the structured tool. Good results have been observed when the characteristic height is at least 2-10 times greater than the thickness of the transfer layer.

In some embodiments, the contact portions are generally parallel lines or ridges separated by valleys or troughs. The contact portions can have a cross section that is triangular, rectangular, trapezoidal, or square and have a characteristic height of at least 2.5 microns, at least 12 microns, at least 25 microns, or at least 100 microns. Such a structured tool can be prepared by microreplication techniques as disclosed in U.S. Pat. Nos. 5,175,030; 5,183,597; 7,282,272.

The inventors have determined that when the contact portions of the structured tool comprise a triangular cross section in a preferred embodiment, finer patterns can be produced in the substrate since the contact portions can make essentially line contact (prism contact portion) or point contact (pyramid contact portion) with the substrate at the vertex of the triangular cross section. More surprisingly, this extremely small contact area is sufficient to remove the transfer layer from the substrate leaving openings that extend all the way through the transfer layer to the substrate. The triangular cross section not only helps to improve the rigidity of the contact portion in use, but allows for much finer patterned lines to be formed on the substrate.

In many convenient embodiments, the transfer layer comprises a wax, although non-waxy polymers may be used provided that the substance of the transfer layer has two properties. First it must have a greater adhesion to the structured tool than it has for the substrate during the step of withdrawing of the structured tool. Second, the adhesion for the tool must be sufficiently great that it defeats the cohesive forces in the transfer layer so that it fails all the way to the substrate when the structured tool is withdrawn. In many convenient embodiments, the transfer layer is laid down on the substrate such that it has a thickness of between about 50 nanometers to about 5 microns. After the step of withdrawing of the structured tool, the predetermined pattern that remains can have features with a dimension, such as the width of a repeating line, of less than 50 microns, 40 microns, 30 microns, 20 microns, 10 microns, or even less 5 microns.

In many convenient embodiments, the substrate is a flexible material such as polyethylene terephthalate (PET) or polyethylene naphthalate (PEN). In these embodiments, it is often convenient to perform the process of the present invention as a roll-to-roll process. In these embodiments, the structured tool can be an indefinite length web that is laminated or pressed onto the flexible substrate material or a tool roll having a circular diameter. In some of these embodiments, the step of contacting the transfer layer with the structured tool is performed in a nip between two rolls, one of which is a backup roll. Depending on materials and process conditions, the backup roll can be either rigid (metallic) or resilient (elastomeric). It has further been observed that when the process of the present invention is used in a roll-to-roll process, it is possible to advance the substrate at a speed of at least 4 feet/min, but much higher speeds are possible depending on the apparatus and processing conditions used.

After the step of withdrawing the structured tool, leaving behind openings in what had before been the continuous transfer layer, one of the ways to make use of the predetermined pattern is to deposit a conductive layer on the substrate in the gaps following the predetermined pattern. For example, such a conductive layer could comprise indium-tin-oxide or other metals such as copper, silver, or gold applied by sputter deposition. As an alternative example, the conductive layer can comprise an electrolessly plated metal layer. When an electrolessly plated metal layer is wanted, it may be convenient to provide a tie or seed layer for good adhesion to the substrate. For example, when the intent is to electrolessly plate a copper layer, good results have been obtained by first sputter-depositing a palladium layer.

Some other embodiments use the transfer layer material that has adhered to the structured tool after withdrawal from the substrate. In these embodiments, after the structured tool is withdrawn from the polymer transfer layer, the structured tool is put into contact against a receiving film, so as to thermally transfer the portions of the transfer layer that were separated with the structured tool onto the receiving film. The receiving film then has a negative-image of the predetermined pattern that has been left on the substrate, and can go on to receive other processing such as the addition of a conductive layer.

In one embodiment, the invention is a method of forming a substrate having a transfer layer with a predetermined pattern on a first major surface of the substrate, the method comprising: providing the substrate having the transfer layer on the first major surface; providing a structured tool having a body and a plurality of contact portions, the contact portions having a Young's Modulus between about 0.5 Gpa to about 30 Gpa; heating either the structured tool or the substrate; contacting the transfer layer with the structured tool; cooling the transfer layer; and withdrawing the structured tool from the transfer layer such that portions of the transfer layer separate with the structured tool leaving openings in the transfer layer that extend all the way through the transfer layer to the substrate forming the transfer layer with the predetermined pattern.

### DEFINITIONS

In connection with this disclosure, the phrase, “transfer layer,” does not mean that the transfer layer needs to cover the entire first major surface, only that the transfer layer is substantially continuous within some region intended to be contacted by the structured tool.

### DESCRIPTION OF THE DRAWINGS

FIG. 1a shows schematically a stage in one aspect of a method according to the present invention, specifically a structured tool adjacent to a substrate.

FIG. 1b shows a later stage of the process of FIG. 1a, with the structured tool pressed into the transfer layer.

FIG. 1c shows a later stage of the process of FIG. 1b, wherein the structured tool has been stripped from the substrate, causing the transfer layer to fracture with portions remaining attached to the structured tool.

FIG. 1d shows a later stage of the process of FIG. 1c, where the structured tool has been moved away leaving openings extending through the transfer layer to the first major surface of the substrate.

FIG. 2a shows one stage in an optional process of metal disposition onto the patterned substrate of FIG. 1d.

FIG. 2b shows a later stage of the process of FIG. 2a in which the transfer layer has been entirely removed leaving a metal pattern on the substrate.

FIG. 2c shows a later stage of the process of FIG. 2b, wherein an additional metal layer has been added to the metal pattern of FIG. 2b.

FIG. 3 shows a schematic view of an apparatus for forming a substrate having a transfer layer with a predetermined pattern in a roll-to-roll process.

FIG. 4 shows a schematic view of an alternate apparatus for forming a substrate having a transfer layer with a predetermined pattern in a roll-to-roll process.

FIG. 5 shows a predetermined pattern in an ink transfer layer on a PET substrate.

FIG. 6 shows another predetermined pattern in a copper layer on a PET substrate.

### DETAILED DESCRIPTION

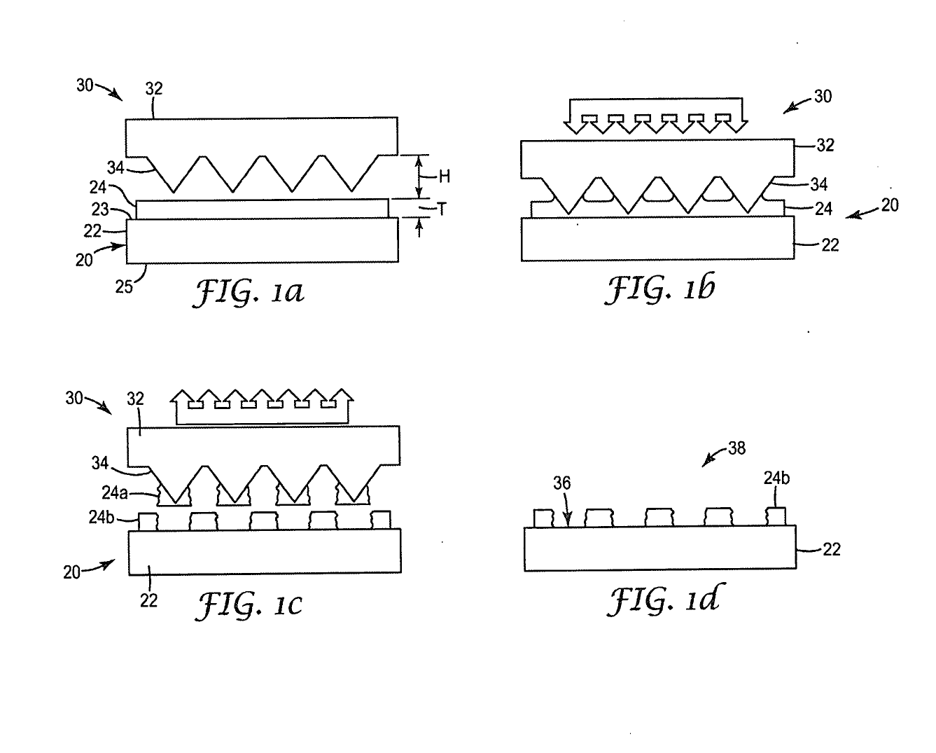

Referring now to FIG. 1a, one stage in a method according to the present invention is illustrated. A multilayer film 20 is provided, including a substrate 22 having a first major surface 23 and a second major surface 25 opposing the first major surface, and a transfer layer 24 applied to at least a portion of the first major surface. The transfer layer 24 does not have to cover the entire first major surface 23, although in many convenient embodiments the transfer layer is continuous within at least a portion of the first major surface. In one embodiment, the transfer layer 24 has a generally uniform thickness designated as “T”.

Adjacent to the multilayer film 20 is a structured tool 30. The depicted structured tool 30 includes a body portion 32 having a plurality of contact portions 34 attached to the body. The contact portions are semi-rigid having a Young's Modulus as previously discussed. The contact portions conveniently have a generally uniform characteristic height designated as “H”. It has been observed that it can be helpful for the characteristic height of the contact portion to be larger than the thickness of the transfer layer. Good results have been observed when the characteristic height is at least 2-500 times greater, or 2 to 100 times greater, or 2 to 50 times greater, or 2 to 10 times greater, or 2 to 5 times greater than the thickness of the transfer layer. It is believed that as the structured tool is pressed into the liquefied transfer layer, sufficient volume needs to be present in the valley areas between the contact portions to allow for some displacement of the liquefied transfer layer into these regions. By designing the contact portions of the structured tool to be sufficiently tall, the transfer layer will not come into contact with the valleys between adjacent contact portions thereby cleanly severing the transfer layer when the structured tool is removed after cooling.

In some embodiments, the contact portions are generally parallel lines or ridges separated by valleys or troughs. The contact portions can have a cross section that is triangular, rectangular, trapezoidal, or square and have a characteristic height of at least 2.5 microns, at least 12 microns, at least 25 microns, or at least 100 microns, or even up to about 1 mm. In one embodiment, the contact portions comprise a plurality of parallel triangular prisms extending across on the surface of the structured tool.

Referring now to FIG. 1b, a later stage of the process of FIG. 1a is illustrated. In this figure, the structured tool 30 has been pressed into contact with the transfer layer 24. In some embodiments, the structured tool has been pressed at least ½ the distance through the transfer layer thickness, at least ¾ the distance through the transfer layer thickness, or substantially through the entire transfer layer thickness. The transfer layer has been heated to a liquefied state by an appropriate heating source. The heating can be applied to either the structured tool 30 or the substrate 22 and thereby indirectly to the transfer layer 24. Heating of the transfer layer, can be performed directly via radiant or convective energy, or indirectly via conduction through the substrate 22 or the structured tool 30. In many convenient embodiments, the heat is applied to the structured tool 30 prior to first contact with the transfer layer 24. After contact has been made between the structured tool 30 and the transfer layer 24, cooling is applied to the transfer layer 24. This may be done via convective energy, or indirectly via conduction through the substrate 22 or the structured tool 30. In many convenient embodiments, the cooling is applied via conduction through the substrate 22, or is allowed to happen passively to the environment.

Referring now FIG. 1c, a later stage of the process of FIG. 1b is illustrated. In this view, the structured tool 30 has been stripped from the multilayer film 20. Associated with the movement, the detached portions 24a of the transfer layer 24 have remained with the structured tool 30 so as to leave openings in the transfer layer 24 defined by retained portions 24b.

Referring now to FIG. 1d, the structured tool has been moved completely away leaving openings 36 in the transfer layer 24 extending all the way through the transfer layer to the first major surface 23 of substrate 22 thereby forming a transfer layer with a predetermined pattern 38 on the substrate.

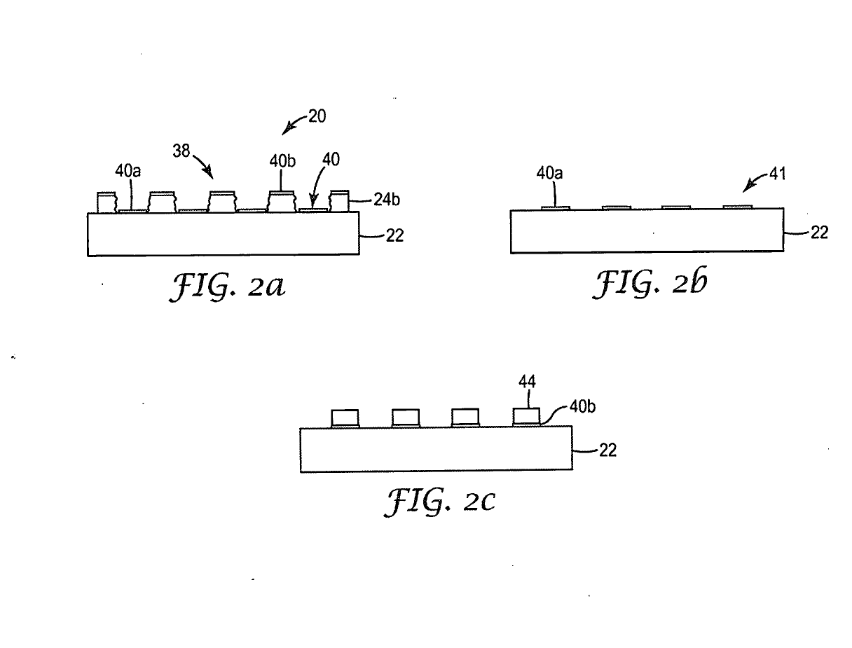

Referring now to FIG. 2a, one stage in an optional additional process using the present invention starting from the patterned substrate of FIG. 1d is illustrated. In this figure, material 40 has been deposited across the surface of the multilayer film 20 having the transfer layer with the predetermined pattern 38. Some of material 40 has been deposited directly on the first major surface 23 of substrate 22 (reference 40a), whereas some of the material 40 has been deposited instead on the transfer layer with the predetermined pattern 38 (remaining portion of transfer layer 24 and reference numeral 40b). Numerous methods can be used to apply material 40 depending on its nature. For example, sputter deposition can be used to lay down a transparent, conductive layer of indium-tin-oxide. Sputter deposition can also be used to lay down a seed layer for further processing.

Referring now to FIG. 2b a later stage of the process of FIG. 2a is illustrated. In this figure, the transfer layer with the predetermined pattern 38 (remaining portions of transfer layer 24 in FIG. 2a) has been entirely removed by solvent or heat, leaving only material 40a forming a second predetermined pattern 41.

Referring now to FIG. 2c a later stage of the process of FIG. 2b is illustrated. In this figure, an additional layer 44 has been deposited onto the second predetermined pattern 41 of material 40a. One useful embodiment of the invention involves sputter depositing a seed layer of palladium at the stage illustrated in FIG. 2a, and using electroless plating to deposit an additional layer 44 of conductive copper traces on the second predetermined pattern 41 comprising the seed layer of palladium illustrated in FIG. 2b.

In another embodiment, instead of plating a copper layer onto the first major surface 23 in the openings 36 of the predetermined pattern 38, the transfer layer 24 can be applied over a first major surface 23 comprising a copper layer thereby forming a multilayer film comprising a substrate, a copper layer and a transfer layer. The copper layer or metal layer such as silver, aluminum, or gold can be applied by techniques to known to those of skill in the art such as sputter coating or evaporative metal coating. Once the predetermined pattern 38 in the transfer layer 22 is formed, the exposed copper areas or metal layer in openings 36 of the predetermined pattern 38 can be etched away leaving a predetermined pattern 38 in the copper layer or metal layer after removal of the transfer layer by solvents.

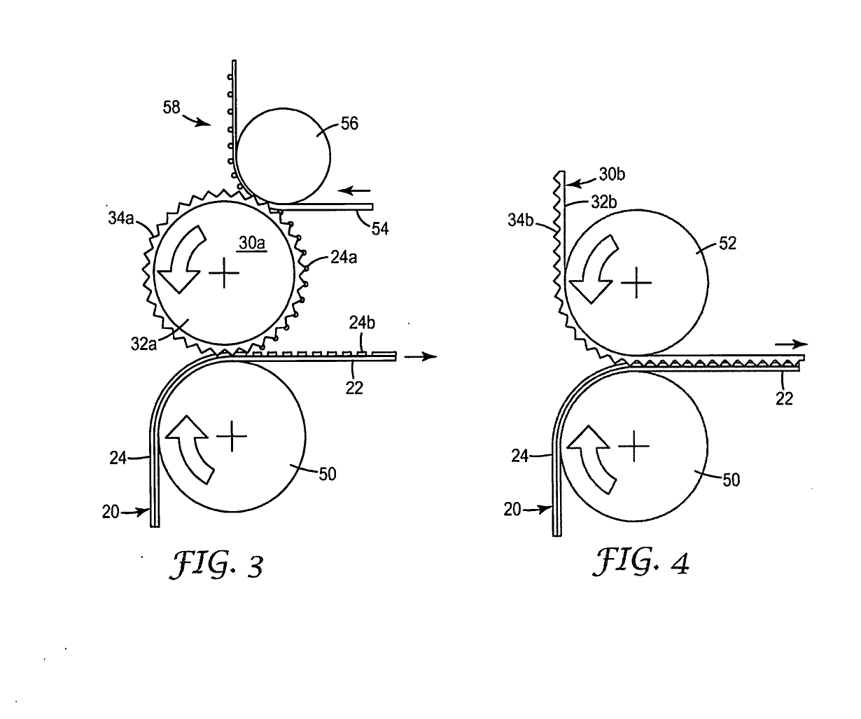

Referring now to FIG. 3, a schematic view of an apparatus for forming a substrate having a polymer layer with a predetermined pattern in a roll-to-roll process is illustrated. Multilayer film 20 is advanced into a nip between a structured tool in the form of a tool roll 30a and a backup roll 50. The tool roll 30a has a body 32a and contact portions 34a. In this view, detached portions 24a of the transfer layer 24 can be seen remaining with the tool roll 30a so as to leave openings extending through the transfer layer to the substrate 22 thereby forming a transfer layer with a predetermined pattern 38 defined by retained portions 24b. Optionally, the detached portions 24a of the transfer layer can be placed into contact with a receiving film 54 that is advanced through a second nip with the tool roll 30a and a second backup roll 56. The detached portions 24a can then adhere to the receiving film 54 forming a negative-image 58 of the predetermined pattern 38 on the receiving film 54. If needed, a suitable cleaning station such as a brush roll with a solvent bath and a dryer can be provided to remove any residue from the tool roll 30a after contact with the receiving film and then dry the tool roll for contact with the transfer layer 24 again.

Referring now to FIG. 4, a schematic view of an alternate apparatus for forming a substrate having a transfer layer with a predetermined pattern in a roll-to-roll process is illustrated. Multilayer film 20 is advanced into a nip between a solid roll 52 and a backup roll 50. The structured tool in this embodiment is in the form of a structured film 30b having a body 32b and contact portions 34b. Such films are available from 3M Corporation, St. Paul and sold as Vikuiti™ Brightness Enhancing Films. Typical brightness enhancement films have a prism angle of 90 degrees, a prism pitch of 24 or 50 μm, and an applied thickness between 62 to 275 μm. An advantage of this embodiment is that the withdrawing of the structured film 30b need not accomplished immediately. The temporary lamination of the structured film 30b and multilayer film 20 may be wound up into a roll so that the withdrawing step can be performed later at a convenient time and place.

In various embodiments of the invention, the transfer layer can comprise waxes, polymer resists, inks, or photoimageable resists such as Furturrex NR-9 1000PY. Suitably, the transfer layer can be between about 50 nanometers to about 5 microns thick. In some embodiments, when using a structured tool having a triangular cross sectional geometry, thinner transfer layers can result in openings in predetermined pattern having widths less than about 20 microns, less than about 10 microns, or even less than about 5 microns.

### EXAMPLES

### Example 1

A substrate having a transfer layer (DNP M290 Near-Edge Wax/Resin Thermal Transfer Ribbon (Dai Nippon Printing Co., Ltd., Tokyo, Japan)) was placed in contact with a section of PET microreplicated film acting as a structured tool. The structured tool comprised a rectangular body portion 32 having a plurality of contact portions 34 attached to the body portion similar to the structured tool 30 shown in FIG. 1a. The contact portions comprised parallel, triangular prisms (isosceles triangular cross section) having a height of 100 μm, a pitch of 200 μm, and a 90 degree angle at the contacting tip between the equal sides of the triangle.

The DNP Transfer Ribbon and microreplicated structured tool were fed into the lamination nip of a ChemInstruments Hot Roll Laminator (Faifield, Ohio), with the DNP Transfer ribbon in contact with the heated roll. The temperature of the hot roll was set to 180 degrees F., the Speed Control setting was positioned between 10 and 20 (approximately 2.5 to 5.0 ft/min), and the nip pressure was set to 2 psi. After exiting the lamination nip, the lamination was allowed to cool to room temperature.

The DNP Transfer ribbon was peeled from the microreplicated structured tooling, transferring wax from the ribbon to the contact portions of the structured tool and leaving openings in the wax transfer layer extending to the first major surface of the transfer ribbon. The openings were approximately 20 μm wide on a 200 μm pitch, leaving stripes of transfer layer material in a predetermined pattern 38 approximately 180 μm wide separated by 20 μm openings 36 similar to the pattern shown in FIG. 1d.

### Example 2

A substrate comprising a portion of a 5 mil thick piece of PET was uniformly blackened with a black Fine/Chisel Super Sharpie Twin Tip permanent marker (Sanford Corporation, Oak Brook, Ill.), to form an ink transfer layer on the first major surface which was placed in contact with a microreplicated structured tool. The structured tool comprised a rectangular body portion having a plurality of parallel, trapezoidal-shaped contact portions attached to the body portion. In cross section, the height and pitch of the trapezoidal-shaped elements were 175 μm and 350 μm respectively, and the horizontal top portion of the trapezoidal-shaped contact portion initially touching the transfer layer was approximately 200 μm wide.

The substrate and microreplicated structured tool were fed into the lamination nip of a ChemInstruments Hot Roll Laminator (Faifield, Ohio), with the ink transfer layer in contact with the heated roll. The temperature of the hot roll was set to 180 degrees F., the Speed Control setting was positioned between 10 and 20 (approximately 2.5 to 5.0 ft/min), and the nip pressure was set to 2 psi. After exiting the lamination nip, the lamination was allowed to cool to room temperature.

The substrate was then peeled from the microreplicated structured tool, transferring portions of the ink transfer layer from the 5 mil thick PET to the contact portions of the microreplicated structured tool and leaving openings extending to the first major surface of the PET substrate. The openings were approximately 200 μm wide on a 350 μm pitch, leaving stripes of ink transfer layer material in a predetermined pattern 38 approximately 150 μm wide separated by 200 μm openings 36 similar to the pattern shown in FIG. 1d.

### Example 3

A substrate having a transfer layer (Tektronix 3-Color Transfer Roll (for Phaser™ Thermal-wax Printers, Reorder No. 016-0906-01), Beaverton, Oreg.) was placed in contact with a section of PET microreplicated film acting as a structured tool. The structured tool comprised a rectangular body portion 32 having a plurality of contact portions 34 attached to the body portion similar to the structured tool 30 shown in FIG. 1a. The contact portions comprised parallel, triangular prisms (isosceles triangular cross section) having a height of 100 μm, a pitch of 200 μm, and a 90 degree angle at the contacting tip between the equal sides of the triangle.

The 3-Color Transfer Ribbon and microreplicated structured tool were fed into the lamination nip of a ChemInstruments Hot Roll Laminator (Faifield, Ohio), with the 3-Color Transfer ribbon in contact with the heated roll. The temperature of the hot roll was set to 230 degrees F., the Speed Control setting was positioned between 10 and 20 (approximately 2.5 to 5.0 ft/min), and the nip pressure was set to 2 psi. After exiting the lamination nip, the lamination was allowed to cool to room temperature.

The Tektronix 3-Color Transfer ribbon was then peeled from the microreplicated structured tooling, transferring wax from the ribbon onto the contact portions of the structured tool and leaving openings in the wax transfer layer extending to the first major surface of the transfer ribbon.

The microreplicated structured tool, with wax transfer layer attached to the contact portions (similar to reference numeral 30 in FIG. 1c), was placed into contact with a 5 mil thick PET receiving film and fed into the lamination nip of the Hot Roll Laminator. The temperature of the hot roll was set to 230 degrees F., the Speed Control setting was positioned between 10 and 20 (approximately 2.5 to 5.0 ft/min), and the nip pressure was set to 2 psi. After exiting the lamination nip, the lamination was allowed to cool to room temperature.

The PET receiving film was then peeled from the structured tool forming a negative-image of the predetermined pattern. The negative-image of the predetermined pattern comprised a plurality of stripes similar to FIG. 1d approximately 75 μm wide on a 200 μm pitch with the openings between the stripes approximately 125 μm wide.

### Example 4

A transfer layer was fabricated by extracting ink from an Expo vis-à-vis Wet Erase Fine Point Pen (Sanford Corporation, Oak Brook, Ill), diluting the extracted ink to 5.8% solids-to-solvent (measured by mass) in isopropyl alcohol, coating a section of 5 mil thick PET with the diluted ink using a #4 Meyer Rod from RDS (Webster, N.Y.), and allowing the solvent to evaporate. The dried ink thickness of the transfer layer was approximately 0.5 μm.

The PET substrate with the ink transfer layer was placed in contact with a section of microreplicated film, the microreplicated film acting as a structured tool. The structured tool comprised a rectangular body portion 32 having a plurality of contact portions 34 attached to the body portion similar to the structured tool 30 shown in FIG. 1a. The contact portions comprised parallel, triangular prisms (isosceles triangular cross section) having a height of 2.5 μm, a pitch of 5 μm, and a 90 degree angle at the contacting tip between the equal sides of the triangle.

The PET substrate with the ink transfer layer and the microreplicated structured tool were fed into the lamination nip of a ChemInstruments Hot Roll Laminator (Faifield, Ohio), with the fabricated transfer film in contact with the heated roll. The temperature of the hot roll was set to 180 degrees F., the Speed Control setting was positioned between 10 and 20 (approximately 2.5 to 5.0 ft/min), and the nip pressure was set to 2 psi. After exiting the lamination nip, the lamination was allowed to cool to room temperature.

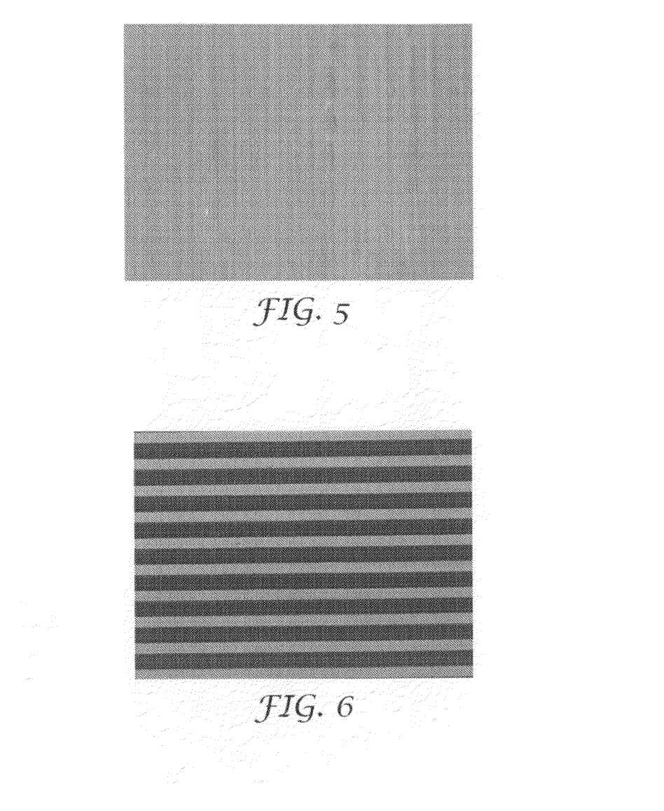

The PET substrate was peeled from the microreplicated structured tool, transferring ink from transfer layer onto the contact portions of the structured tool leaving openings extending to the first major surface of the PET substrate. The openings were approximately 3 μm wide on a 5 μm pitch, leaving stripes of ink transfer layer material in a predetermined pattern 38 approximately 2 μm wide separated by 3 μm openings 36 as shown in FIG. 5.

### Example 5

A substrate having a transfer layer (Tektronix 3-Color Transfer Roll (for Phaser™ Thermal-wax Printers, Reorder No. 016-0906-01) of Beaverton, Oreg.) was placed in contact with a section of microreplicated film (90/50 Brightness Enhancement Film from 3M Corporation, Saint Paul, Minn.) with the film acting as a structured tool. The structured tool comprised a rectangular body portion 32 having a plurality of contact portions 34 attached to the body portion similar to the structured tool 30 shown in FIG. 1a. The contact portions comprised parallel, triangular prisms (isosceles triangular cross section) having a height of 25 μm, a pitch of 50 μm, and a 90 degree angle at the contacting tip between the equal sides of the triangle.

The 3-Color Transfer Ribbon and microreplicated structured tool were fed into the lamination nip of a ChemInstruments Hot Roll Laminator (Faifield, Ohio), with the 3-Color Transfer Ribbon in contact with the heated roll. The temperature of the hot roll was set to 230 degrees F., the Speed Control setting was positioned between 10 and 20 (approximately 2.5 to 5.0 ft/min), and the nip pressure was set to 2 psi. After exiting the lamination nip, the lamination was allowed to cool to room temperature.

The 3-Color Transfer Ribbon was peeled from the microreplicated structured tooling, transferring wax from the ribbon onto the contact portions of the structured tool and leaving openings extending to the first major surface of the transfer ribbon.

The microreplicated structured tool, with transferred wax attached to the contact portions (similar reference numeral 30 in FIG. 1c), was placed into contact with a 5 mil thick PET receiving film and fed into the lamination nip of the Hot Roll Laminator. The temperature of the hot roll was set to 230 degrees F., the Speed Control setting was positioned between 10 and 20 (approximately 2.5 to 5.0 ft/min), and the nip pressure was set to 2 psi. After exiting the lamination nip, the lamination was allowed to cool to room temperature, and the PET receiving film was separated from the microreplicated structured tool leaving a negative-image predetermined pattern on the receiving film's surface.

The PET receiving film was placed into a vapor coating apparatus and the receiving film was vapor coated with an approximately 100 nanometers thick layer of indium-tin-oxide over the entire surface similar to FIG. 2a. The negative-image predetermined pattern formed from the transfer layer was then removed by gently rubbing the vapor coated surface with a heptane soaked rag. The PET receiving film was left bearing its patterned ITO layer comprising parallel ITO lines approximately 10-15 microns wide separated by 50 microns on center in the second predetermined pattern similar to FIG. 2b.

### Example 6

A portion 5 mil thick PET film, vacuum coated with between 50 and 100 nm of silver, was uniformly marked with a red Fine Point Sharpie permanent marker (Sanford Corporation, Oak Brook, Ill.), and then placed into contact with a microreplicated structured tool. The structured tool comprised a rectangular body portion having a plurality of parallel, trapezoidal-shaped contact portions attached to the body portion. In cross section, the height and pitch of the trapezoidal-shaped elements were 175 μm and 350 μm respectively, and the horizontal top portion of the trapezoidal-shaped contact portion initially touching the transfer layer was approximately 200 μm wide.

The substrate with the ink transfer layer and microreplicated structured tool were fed into the lamination nip of a ChemInstruments Hot Roll Laminator (Faifield, Ohio), with the transfer film in contact with the heated roll. The temperature of the hot roll was set to 180 degrees F., the Speed Control setting was positioned between 10 and 20 (approximately 2.5 to 5.0 ft/min), and the nip pressure was set to 2 psi. After exiting the lamination nip, the lamination was allowed to cool to room temperature.

The substrate was then peeled from the microreplicated structured tool, transferring portions of the red ink transfer layer to the contact portions of the structured tool, leaving openings extending to the silver coated first major surface of the substrate. The substrate was placed into a MacDermid Copper M-85 electroless plating bath (MacDermid, Waterbury, Conn.) for approximately 30 minutes, until a layer of copper had clearly formed on the exposed regions of silver. The predetermined pattern in the transfer layer was washed away in a bath of methyl ethyl ketone leaving a second predetermined pattern of copper traces on the silver coated substrate. The lines of patterned copper were approximately 200 μm wide on a 350 μm pitch.

### Example 7

A 5 mil thick PET film was sputter coated with copper approximately 100 nm. The copper-coated PET film was coated with a liquid solution of 25% by weight Futurrex NR-9 1000PY polymer resist solution (Futurrex, Inc., Franklin, N.J.) diluted in 75% by weight Methyl Ethyl Ketone (MEK), such that the final liquid composition was approximately 5% by weight polymer and 95% by weight solvent. The liquid solution was applied to the copper-coated substrate with a #4 draw-down rod (RDS Corp, Webster, N.Y.). The solvent was allowed to dry in air at room temperature, leaving a uniform coating of dried polymer resist forming a transfer layer approximately 0.5 microns thick.

The PET copper coated film with transfer layer was placed in contact with a microreplicated structured tool. The structured tool comprised a rectangular body portion having a plurality of parallel, trapezoidal-shaped contact portions attached to the body portion. In cross section, the height and pitch of the trapezoidal-shaped elements were 175 μm and 350 μm respectively, and the horizontal top portion of the trapezoidal-shaped contact portion initially touching the transfer layer was approximately 200 μm wide.

The PET copper coated film with transfer layer and the microreplicated stamp were fed into the lamination nip of a ChemInstruments Hot Roll Laminator (Faifield, Ohio), with the transfer layer in contact with the heated roll. The temperature of the hot roll was set to 150 degrees F., the Speed Control setting was positioned between 10 and 20 (approximately 2.5 to 5.0 ft/min), and the nip pressure was set to 2 psi.

After exiting the lamination nip, the lamination was allowed to cool to room temperature. The structured tool was then peeled from the transfer layer of the PET film to reveal a predetermined pattern in the transfer layer having stripes of polymer resist 150 μm wide separated by lanes free of polymer resist (openings) 200 μm wide. In the lanes free of the polymer resist, the copper coating is exposed on the first major surface.

The PET substrate with the predetermined pattern in the transfer layer was then placed into a copper etch bath, to remove the exposed copper in the openings of the predetermined pattern in the transfer layer. The copper etch bath comprised 1% by weight Ferric Chloride in 99% by weight water (VWR Inc., Weschester, Pa.). The PET substrate was then removed from the copper etch bath when it was observed that all copper in lanes free of polymer resist had been etched (approximately 2 minutes). After removing the predetermined pattern in transfer layer with a solvent, the PET substrate then had a predetermined pattern of copper lines approximately 150 μm wide separated on a 350 μm pitch. FIG. 6 shows the predetermined pattern in the copper layer on the PET substrate after etching.

While the invention has been particularly shown and described with reference to various embodiments thereof, it will be understood by those skilled in the art that various other changes in the form and details may be made therein without departing from the spirit and scope of the invention.

What is claimed is:

1. A method of forming a substrate having a transfer layer with a predetermined pattern on a first major surface of the substrate, the method comprising:
providing the substrate having the transfer layer on the first major surface;
providing a structured tool having a body and a plurality of contact portions, the contact portions having a Young's Modulus between about 0.5 Gpa to about 30 Gpa;
heating either the structured tool or the substrate;
contacting the transfer layer with the structured tool;
cooling the transfer layer; and
withdrawing the structured tool from the transfer layer such that portions of the transfer layer separate with the structured tool leaving openings in the transfer layer that extend all the way through the transfer layer to the substrate forming the transfer layer with the predetermined pattern.

2. The method according to claim 1 wherein the transfer layer has a thickness of between about 50 nanometers to about 5 micrometers.

3. The method according to claim 1 wherein the plurality of contact portions having a characteristic height and the characteristic height is at least 2-10 times greater than the thickness of the transfer layer.

4. The method according to claim 3 wherein the plurality of contact portions comprise a triangular cross section and have the characteristic height of at least 12 microns.

5. The method according to claim 1 wherein the structured tool is microreplicated.

6. The method according to claim 5 wherein the structured tool is a tool roll.

7. The method according to claim 6 wherein the contacting is performed between the tool roll and a backup roll.

8. The method according to claim 1 wherein the contacting is performed while the substrate is a strip of indefinite length material being advanced through a nip in a roll-to-roll process.

9. The method according to claim 1 wherein the transfer layer comprises a wax.

10. The method according to claim 1 wherein the openings comprise a width of less than 20 microns.

11. The method of claim 10 wherein the predetermined pattern comprises stripes extending across the first major surface.

12. The method according to claim 1 further comprising depositing a conductive layer on the substrate forming a second predetermined pattern.

13. The method according to claim 12 wherein the conductive layer comprises indium-tin-oxide.

14. The method according to claim 12 wherein the conductive layer comprises an electrolessly plated metal layer.

15. The method according to claim 14 wherein the conductive layer comprises an electrolessly plated copper layer over a sputter-deposited palladium layer.

16. The method according to claim 1 wherein the first major surface comprises a metal layer and the substrate is etched to remove the metal layer from the openings in the predetermined pattern.

17. The method according to claim 1 further comprising contacting the structured tool against a receiving film, after withdrawing the structured tool from the transfer layer, to thermally transfer the portions of the transfer layer that separated with the structured tool onto the receiving film in a negative-image of the predetermined pattern.

18. The method according to claim 17 further comprising depositing a conductive layer on the receiving film.

19. The method according to claim 1 wherein the contact portions have a Young's modulus between about 3 Gpa to about 7 Gpa.

20. The method of claim 19 wherein the contact portions comprise a triangular cross section.
